(19) United States
(12) Patent Application Publication
(10) Pub. No.: US 2015/0155521 A1
(43) Pub. Date: Jun. 4, 2015

(54) TRANSPARENT SUPPORTED ELECTRODE FOR OLED

(71) Applicant: SAINT-GOBAIN GLASS FRANCE, Courbevoie (FR)

(72) Inventors: Simon Mazoyer, Paris (FR); Fabien Lienhart, San Diego, CA (US); Vincent Sauvinet, Grenoble (FR)

(21) Appl. No.: 14/415,394

(22) PCT Filed: Jul. 16, 2013
(86) PCT No.: PCT/FR2013/051704

§ 371 Date: Jan. 16, 2015

(30) Foreign Application Priority Data
Jul. 17, 2012 (FR) 1256874

(51) Int. Cl. H01L 51/52

(52) U.S. Cl. CPC H01L 51/5215; H01L 51/5209; H01L 51/5268

(57) ABSTRACT

An electrode for an organic light-emitting diode, includes a transparent or translucent non-conductive substrate, having a refractive index of between 1.3 and 1.6; a transparent electrode layer, formed from a transparent conductive oxide or from a transparent conductive organic polymer; a continuous network of metal lines, deposited on the transparent electrode layer, and, as light-scattering structure, a translucent scattering layer having a refractive index of between 1.7 and 2.4, located between the non-conductive substrate and the electrode layer, wherein the continuous network of metal lines consists, at least at the contact interface with the transparent electrode, of a metal or metal alloy having a reflectivity at least equal to 80% over at least one portion of the visible light spectrum.

The present invention relates to a supported electrode intended to be used, preferably as anode, in an organic light-emitting diode.

An organic light-emitting diode (OLED) is an opto-electronic device comprising two electrodes, at least one of which is transparent to visible light, and a stack of thin layers comprising at least one light-emitting layer (EL layer). This light-emitting layer is sandwiched at least between, on the one hand, an electron injection or transport layer (EIL or ETL) situated between the EL layer and the cathode and, on the other hand, a hole injection or transport layer (HIL or HTL) situated between the EL layer and the anode.

The OLEDs that include a transparent electrode support and a transparent electrode in contact therewith are conventionally called substrate-emitting OLEDs or bottom-emitting OLEDs. The transparent electrode is in this case typically the anode.

Similarly, the OLEDs that include an opaque electrode support are called top-emitting OLEDs, the emission then being carried out through the transparent electrode which is not in contact with the support, generally the cathode.

Beyond a given potential threshold, the light power of an OLED directly depends on the potential difference between the anode and the cathode. To fabricate OLEDs of large size exhibiting a uniform light power over their entire surface, it is necessary to limit as far as possible the ohmic drop between the current inputs, generally situated at the edge of the OLEDs, and the center of the OLED. One known way of limiting this ohmic drop is to reduce the sheet resistance (R□ or Rₛ) of the electrodes, typically by increasing their thickness.

Such an increase in the thickness of the electrodes does, however, pose significant problems when it comes to transparent electrodes. In practice, the materials used for these electrodes, for example ITO (Indium Tin Oxide), exhibit an insufficient light transmission and are prohibitively expensive, which means that thicknesses greater than 500 nm are not very advantageous. In practice, the ITO layers do not exceed around 150 nm.

It is well known to reduce or overcome this problem of insufficient conductivity of ITO by lining the anode with a metal grid. The material of choice for the formation of such a grid is of course aluminum, a low-cost metal that has a high conductivity. However, aluminum poses a problem of hillock formation via thermal migration of atoms to the surface of the layers. This phenomenon is the cause of reliability problems of electronic devices. Although the mechanisms for formation of these hillocks are not yet clearly elucidated, a common solution consists in flanking a layer of aluminum with two thin layers of another metal, typically molybdenum (see for example the article Effect of Capping Layer on Hillock Formation in Thin Al Films, in Metals and Materials International, Vol. 14, number 2 (2008), pages 147-150). Triple layer Mo—Al—Mo or Cr—Al—Cr metal grids (MAM grids) are thus commonly used to limit the resistivity of transparent anodes made of ITO in electro-optical devices such as OLEDs (US 2006/0154550, US 2010/0079062).

However, the use of such MAM grids poses a considerable problem in OLEDs comprising light-extraction means located on the outside of the transparent anode.

Such means, well known in the art, are specifically used to limit the trapping phenomenon of the light emitted in the high-index layers of OLEDs (ETL/EL/HTL organic layers and transparent anode). They are generally a high-index enamel containing scattering elements or a rough scattering interface, located between the anode and the substrate. A similar trapping phenomenon of the light in the substrate exists at the glass/air interface and may be limited by an identical means, namely a scattering layer or interface. When the scattering layer or interface is between the anode and the substrate, it is generally referred to as an internal extraction layer (IEL), whilst a scattering means (scattering layer or interface) located on the outside of the substrate is referred to as an external extraction layer (EEL).

The scattering centers of these IELs or EELs, by deflecting the light rays at low angle of incidence, enable them to exit the waveguide where they are trapped. They are deflected either directly toward the outside of the OLED, or toward the inside then reflected by the metal cathode before leaving the OLED.

In its research, that aims to optimize the light efficiency of OLEDs still further, the Applicant noticed that the use of a MAM grid for increasing the conductivity of the anode had a detrimental effect on the overall light efficiency of an OLED comprising an IEL or EEL.

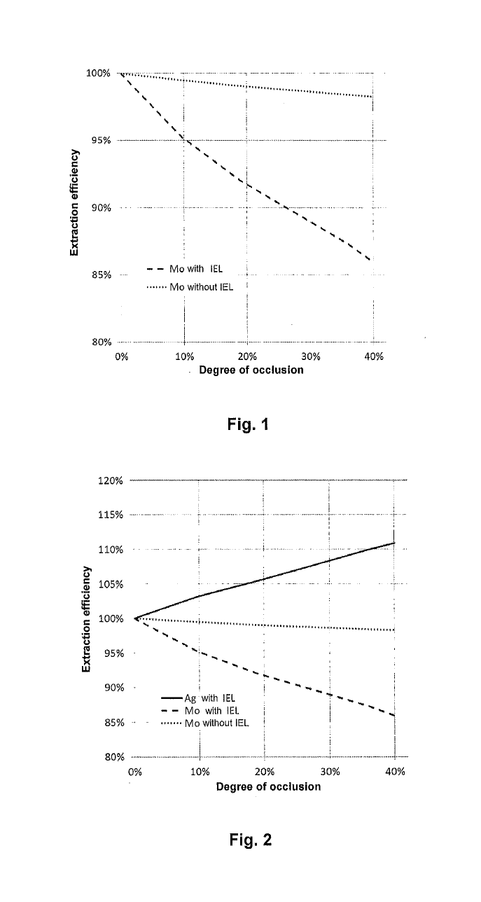

FIG. 1 shows the simulated change of the extraction efficiency in air of an OLED with IEL and of an OLED without IEL, as a function of the degree of occlusion of the active surface of the anode by the MAM metal grid. The active surface of the anode is the zone subjected to the electric field created by the potential between the two electrodes (=area of overlap between the two flat electrodes of the OLED). The extraction efficiency in air is the ratio of the energy flow arriving at the outside of the OLED to the energy flow emitted by the emitting surface, the latter being equal to the active surface not occluded by the metal grid. In FIG. 1, this extraction efficiency in air was set arbitrarily at 100% for the OLED with an IEL layer, and also at 100% for an OLED without IEL, even though it is, in absolute value, lower than the first.

The simulation model that made it possible to obtain these curves was established with the following data:
perfectly transparent glass substrate, n=1.5, thickness 0.7 mm,
IEL, n=1.91, absorption coefficient 1mm⁻, thickness 10 μm,
ITO anode, n=2.0, thickness 110 nm,
grid of a metal characterized by its reflectivity spectrum as a function of the angle of incidence and of the wavelength,
stack of organic layers, n=1.9, absorption coefficient 150 mm⁻¹, thickness 1 μm, with a light source located at the center of the stack,
aluminum cathode, characterized by its reflectivity spectrum as a function of the angle of incidence and of the wavelength.

It is observed that in the absence of an IEL, the extraction efficiency in air decreases very slightly as a function of the degree of occlusion of the anode by the MAM grid. It changes from an efficiency of 100% for a zero degree of occlusion to around 98% for a degree of occlusion of 40%. This small decrease of 2% only is attributed to the absorption, by the molybdenum, of the light rays reflected by the substrate/air interface.

In the presence of an IEL, the extraction efficiency decreases more greatly. It is 5% for a degree of occlusion of only 10%. The IEL seems to amplify the absorption of the light by the electrode grid.

Those skilled in the art thus find themselves faced with the dilemma of having to choose between a good extraction efficiency (at low degree of occlusion) and a satisfactory lighting homogeneity (at higher degree of occlusion).

The present invention enables those skilled in the art to overcome this dilemma. Specifically, the Applicant has discovered that by covering or replacing the molybdenum or chromium of the MAM grids with a high-reflectivity metal, it was possible not only not to reduce the extraction efficiency but to significantly increase it.

Consequently, one subject of the present invention is an electrode for an organic light-emitting diode, successively comprising,
(a) a transparent or translucent non-conductive substrate, having a refractive index of between 1.3 and 1.6,
(b) a transparent or translucent electrode layer, formed from a transparent or translucent conductive oxide or from a transparent or translucent conductive organic polymer, and
(c) a continuous network of metal lines, deposited on the transparent electrode layer, preferably by physical vapor deposition (PVD), especially by vacuum evaporation or by magnetron sputtering, characterized in that it additionally comprises
(d) at least one light-scattering means selected from
a translucent scattering layer having a refractive index of between 1.7 and 2.4, located between the non-conductive substrate (a) and the electrode layer,
a translucent scattering layer having a refractive index greater than or equal to that of the non-conductive substrate, located on the face of the non-conductive substrate which is not facing the electrode layer,
   and in that the continuous network of metal lines consists, at least at the contact interface with the electrode layer, of a metal or metal alloy having a reflectivity at least equal to 80% over at least one portion of the visible light spectrum.

Another subject of the invention is an OLED comprising such an electrode, preferably as anode.

In one preferred embodiment of the invention, the metal or metal alloy at the interface of the grid with the transparent or translucent electrode layer is selected from silver, aluminum and alloys based on silver or aluminum having a mean reflectivity of the visible light (400-700 nm) at least equal to 80%.

However, although silver and aluminum and alloys based on these metals are materials that are particularly preferred for forming the grid of the electrode, they may, in certain particular cases, be replaced by other metals. Specifically, silver and aluminum are characterized by a high reflectivity over the entire spectrum (400-700 nm) which is suitable for white OLEDs. However, when the OLED emits a red light, it may be advantageous to use copper or copper-based alloys which have a high reflectivity in particular for red light. Similarly, when the OLED emits blue light, zinc and zinc alloys may advantageously be used.

The advantages of the use of a high-reflectivity metal at the contact interface between the metal grid and the anode are illustrated in FIG. 2. This graph repeats, for comparison, the two curves from FIG. 1 and additionally represents the simulated change in the extraction efficiency for an OLED with IEL where the molybdenum (reflectivity=35%), at the contact interface with the transparent anode, is replaced by silver (reflectivity=95%). It is observed that, surprisingly, the extraction efficiency in air increases with the degree of occlusion of the anode.

For a degree of occlusion of 10%, the extraction efficiency in air of an OLED according to the invention reaches 103% whereas it is limited to 95% for a comparative OLED with a MAM (Mo—Al—Mo) grid, which represents a gain in efficiency of more than 8%.

Owing to the present invention, those skilled in the art are thus free to increase the degree of occlusion of the anode, without risking degradation of the extraction efficiency in air of the OLED.

This is advantageous for the manufacture of large-size OLEDs. Specifically, a low degree of occlusion, for example of less than 5%, is satisfactory for obtaining sheet resistances (R□) of the order of 2 ohms or more, which enable the manufacture of OLEDs with uniform luminosity having dimensions ranging up to around 50-100 mm.

On the other hand, for larger OLEDs, it is necessary to reduce the R_{□} of the composite anode (ITO+grid) to values of less than or equal to 1 ohm, by increasing the degrees of occlusion to values of greater than 10%. Although a reduction of the R□ by increasing the thickness of the grid can be envisaged for printing techniques using pastes of metallic particles (silver pastes), it is not so for depositions by vacuum evaporation. Indeed, for this technique, used in the present invention, the cost of a coating becomes prohibitive from around 1 μm.

The degree of occlusion of the active zone of the transparent electrode layer by the continuous network of metal lines is preferably between 5% and 50%, in particular between 10% and 35%, and particularly preferably between 15% and 30%.

The present invention thus enables, owing to the increase of the acceptable values for the degrees of occlusion, the manufacture of larger and more efficient OLEDs with uniform luminosity.

The electrodes of the present invention and the OLEDs manufactured from the latter advantageously have sizes such that their smallest dimension is greater than 10 cm, preferably greater than 15 cm and particularly preferably greater than 20 cm.

The active surface area of the OLEDs of the present invention is preferably between 0.02 and 1 m², in particular between 0.05 and 0.5 m².

The gain in efficiency observed also has the following advantage: when the degree of occlusion of the active zone of an OLED increases, the emitting surface and the luminosity of the OLED decrease. This is true irrespective of the nature of the metal of the electrode grid.

Manufacturers, in order to compensate for this loss of luminosity due to the reduction of the emitting surface, could increase the intensity of the current between the two electrodes. This would result however in a highly undesirable reduction in the service life of the OLEDs. Specifically, the service life of the fluorescent or phosphorescent organic compounds of the emitting layers is even shorter when these compounds are passed through by high electric currents. It is generally admitted that it is divided by three when the intensity of the electric current passing through them doubles.

The use of an electrode according to the invention advantageously limits this loss of service life. Thus, for an OLED according to the prior art with IEL and MAM grid, a degree of occlusion of 20% leading to a reduction of the luminosity of around 25%, compensated for by a corresponding increase in the voltage applied, would result in a reduction of the service life of the OLED estimated at 30%. For an OLED according to the invention, a degree of occlusion of 20% leading to a reduction of the luminosity of around 15%, compensated for by a corresponding increase in the voltage, would result in a reduction of the service life of 20% only.

In one preferred embodiment of the present invention, the OLED electrode successively comprises:
(a) a transparent or translucent non-conductive substrate having a refractive index of between 1.3 and 1.6,
(d) a translucent scattering layer (IEL) having a refractive index of between 1.7 and 2.4,
(b) a transparent electrode layer, formed from a transparent conductive oxide or from a transparent conductive organic polymer, and
(c) a continuous network of metal lines in contact with the transparent electrode layer.

The network of metal lines may of course consist completely of silver, of aluminum or of an alloy based on one of these metals. Specifically, these two metals have a conductivity and reflectivity such that they would fulfill their role perfectly.

Silver is however a high-cost metal and it is desirable to limit the amounts used. In the present invention, when the continuous network of metal lines contains silver or a silver-based alloy, this silver is preferably found in the form of a first layer, in contact with the transparent electrode, having a thickness of between 30 and 100 nm. Deposited advantageously on this first layer is an aluminum second layer, having a thickness of between 100 and 500 nm.

The use of a grid consisting solely of aluminum is not recommended either since aluminum has problems of electromigration and/or thermal migration and is conventionally associated with other metal layers, as already explained in the introduction.

In another advantageous embodiment of the present invention, the network of metal lines comprises an MAM structure according to the prior art, namely an Mo—Al—Mo or Cr—Al—Cr three-layer structure, a sufficiently thick layer made of silver or based on silver or a sufficiently thick layer made of aluminum or based on aluminum being inserted between the MAM structure and the transparent anode. It is considered that this silver or aluminum layer is sufficiently thick when it has a thickness of between 30 and 100 nm, preferably of between 50 and 90 nm.

The scattering layers located between the non-conductive substrate and the anode are known in the art and are described, for example, in EP 2 178 343 and WO 2011/089343. As is known, the refractive index of the enamel is preferably greater than or equal to the refractive index of the transparent anode, and the refractive index of the scattering particles is preferably greater than that of the enamel.

Although the chemical nature of the scattering particles is not particularly limited, they are preferably selected from particles of TiO₂ and SiO₂. For optimum extraction efficiency, they are present in the light-scattering means at a concentration of between 10⁴ and 10⁷ particles/mm². The greater the size of the particles, the more their optimum concentration is located toward the lower limit of this range.

The scattering enamel layer generally has a thickness of between 1 μm and 100 μm, in particular between 2 and 50 μm, and particularly preferably between 5 and 30 μm. The scattering particles dispersed in this enamel preferably have a mean diameter, determined by DLS (dynamic light scattering), of between 0.05 and 5 μm, in particular between 0.1 and 3 μm.

The light-extraction means may also be located on the outer face of the substrate, that is to say the face which will be opposite that facing the anode. It may be a network of microlenses or of micropyramids as described in the article in Japanese Journal of Applied Physics, Vol. 46, No. 7A, pages 4125-4137 (2007) or else a satin finish, for example a satin finish produced by hydrofluoric acid etching.

For the anode, it is possible in principle to use any transparent or translucent conductive material having a high enough refractive index, close to the mean index of the HTL/EL/ETL stack. Mention may be made, by way of example of such materials, of transparent conductive oxides such as aluminum-doped zinc oxide (AZO), indium-doped tin oxide (ITO) or tin dioxide (SnO₂). These materials advantageously have an absorption coefficient far below that of the organic materials forming the HTL/EL/ITL stack, preferably an absorption coefficient of less than 0.005, in particular of less than 0.0005.

The anode layer may have a multilayer structure, comprising for example, on a relatively thick base layer, a thinner surface layer, intended to improve the adhesion of the metal grid to the anode. This thin layer may be a metallic layer, for example based on Ti, Ni or Cr. In order for the anode to retain its transparent nature, the thickness of this layer must not exceed around 5 nm, preferably 2 nm (absorption of less than 5%).

The overall thickness of the transparent conductive oxide anode layer is typically between 50 and 200 nm.

When the transparent conductive oxide is not ITO, it is generally recommended to cover the anode layer with an additional thin layer having a higher work function, for example a layer of ITO, MoO₃, WO₃ or V₂O₅.

The techniques for deposition of these oxides such as sputtering, magnetron vacuum deposition, sol-gel or pyrolysis methods, do not generally result in layers that are smooth enough for an application as OLED electrode. It will consequently generally be necessary, after deposition, to carry out a polishing step.

PEDOT (poly(3,4-ethylenedioxythiophene)) is a known electrically conductive organic polymer which could form an interesting alternative to the conductive oxides mentioned above, provided that its refractive index is adjusted, for example, by incorporating nanoparticles of a high index oxide, such as titanium oxide. The possibility of depositing this polymer in liquid form makes it possible in fact to achieve layers with sufficient surface smoothness, which could render the polishing step superfluous.

The continuous network of metal lines is advantageously covered with a passivation layer made of an organic polymer, typically made of polyimide, which mainly serves to prevent short-circuits between these protruding conductive lines and the cathode, which are separated by the very thin stack of the HTL/EL/ETL organic layers.

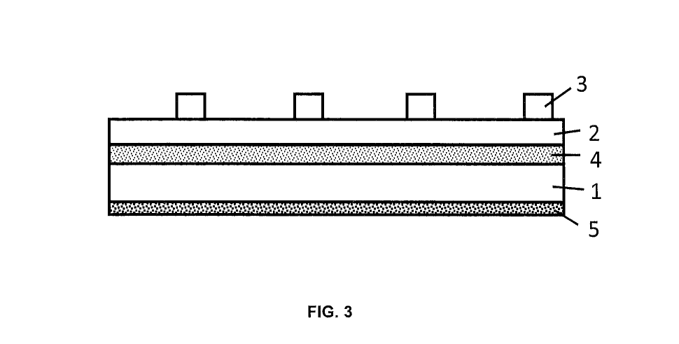

FIG. 3 represents very schematically a supported electrode according to the invention in cross section. This electrode comprises a non-conductive substrate 1 that is essentially transparent, covered on each of its two main faces with a transparent scattering layer 4,5. The scattering layer 5 located at the interface with air is referred to as an external extraction layer (EEL), whereas the scattering layer 4, located on the face facing the inside of the OLED is referred to as an internal extraction layer (IEL). A transparent electrode layer 2 covers the IEL 4. A continuous network of metal lines 3 is deposited on the surface of the transparent electrode layer. This network of metal lines 3 consists, at least at its interface with the transparent electrode 2, of a metal or of an alloy having a mean reflectivity of the visible light at least equal to 80%.

1. An electrode for an organic light-emitting diode, successively comprising:
a transparent or translucent non-conductive substrate, having a refractive index of between 1.3 and 1.6;
a transparent or translucent electrode layer, formed from a transparent or translucent conductive oxide or from a transparent or translucent conductive organic polymer;
a continuous network of metal lines, deposited on the transparent or translucent electrode layer, and
a translucent scattering layer for scattering light and having a refractive index of between 1.7 and 2.4, located between the transparent or translucent non-conductive substrate and the transparent or translucent electrode layer,
wherein the continuous network of metal lines consists, at least at a contact interface with the transparent or translucent electrode layer, of a metal or metal alloy having a reflectivity at least equal to 80% over at least one portion of the visible light spectrum.

2. The electrode as claimed in claim 1, wherein the metal or metal alloy at the contact interface with the transparent or translucent electrode layer is selected from silver, aluminum and alloys based on silver or aluminum having a mean reflectivity of the visible light at least equal to 80%.

3. The electrode as claimed in claim 1, wherein the transparent or translucent electrode layer is an anode layer, and wherein the network of metal lines has a Mo—Al—Mo or Cr—Al—Cr (MAM) three-layer structure, a layer made of silver or made of aluminum or based on silver or aluminum having a thickness of between 30 and 100 nm being inserted between the MAM structure and the anode layer.

4. The electrode as claimed in claim 1, wherein the continuous network of metal lines comprises a first layer, in contact with the transparent or translucent electrode layer, consisting of silver or of a silver-based alloy, having a thickness of between 30 and 100 nm, and, on this said first layer, a second layer consisting of aluminum, having a thickness of between 100 and 500 nm.

5. The electrode as claimed in claim 1, wherein a degree of occlusion of an active zone of the transparent or translucent electrode layer by the continuous network of metal lines is between 5% and 50%.

6. The electrode as claimed in claim 1, wherein the continuous network of metal lines is covered with a passivation layer.

7. The electrode as claimed in claim 1, wherein the transparent or translucent electrode layer is an anode layer and has a thickness of between 50 and 200 nm.

8. The electrode as claimed in claim 1, wherein the translucent scattering layer contains scattering particles in an amount of between 10⁴ to 10⁷ particles/mm² of electrode surface area.

9. An organic light-emitting diode comprising an electrode as claimed in claim 1.

10. The organic light-emitting diode as claimed in claim 8, wherein an active surface area of the organic light-emitting diode is between 0.02 m² and 1 m².

11. The electrode as claimed in claim 5, wherein the degree of occlusion is between 10% and 35%.

12. The electrode as claimed in claim 11, wherein degree of occlusion is between 15% and 30%.

13. The organic light-emitting diode as claimed in claim 9, wherein the electrode is an anode.

14. The organic light-emitting diode as claimed in claim 10, wherein the active surface area is between 0.05 m² and 0.5 m².
